(19) United States
(12) Patent Application Publication
(10) Pub. No.: US 2026/0363030 A1
(43) Pub. Date: Nov. 12, 2026

(54) SEMICONDUCTOR DEVICE AND METHOD OF DETECTING BONDING DEFECTS IN SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/315,867

(22) Filed: Sep. 2, 2025

(30) Foreign Application Priority Data
May 7, 2025 (KR) 10-2025-0058865

(51) Int. Cl. H10P 74/00; G01R 31/28; H10P 74/20; H10W 72/90

(52) U.S. Cl. CPC H10P 74/273; G01R 31/2884; H10P 74/203; H10W 72/967

(57) ABSTRACT

According to embodiments of the present disclosure, a semiconductor device includes: a first bonding pad disposed on a substrate; a second bonding pad bonded to the first bonding pad; a first test pad disposed on a same layer as the second bonding pad, and including a first pad portion, a second pad portion spaced apart from the first pad portion, and a first connection portion connecting the first pad portion and the second pad portion; a first probing pad connected to the first pad portion through first test contacts disposed on the first pad portion; and a second probing pad connected to the second pad portion through second test contacts disposed on the second pad portion.

### CROSS-REFERENCE TO RELATED APPLICATIONS

The present application claims priority under 35 U.S.C. § 119(a) to Korean Patent Application No. 10-2025-0058865 filed on May 7, 2025, which is incorporated herein by reference in its entirety.

### BACKGROUND

### 1. Technical Field

Embodiments of the present disclosure relate to a semiconductor device and a method for detecting a bonding defect in a semiconductor device.

### 2. Related Art

As semiconductor devices become more highly integrated, techniques for stacking semiconductor devices in a vertical direction are being developed. For example, integrated circuits may be formed on two separate wafers, and the two wafers may be bonded using a wafer bonding technique. When manufacturing a semiconductor device using a wafer bonding technique, it is important to prevent defects from occurring at the bonding interface.

### SUMMARY

The objects of embodiments of the present disclosure are not limited to those described herein, and other objects that are not described will be clearly understood by those skilled in the art from the following description.

Embodiments of the present disclosure may provide a semiconductor device and a method for detecting a bonding defect in the semiconductor device, capable of detecting a defect occurring at a bonding interface.

Embodiments of the present disclosure may provide a semiconductor device comprising: a first bonding pad disposed on a substrate; a second bonding pad bonded to the first bonding pad; a first test pad disposed on a same layer as the second bonding pad, and including a first pad portion, a second pad portion spaced apart from the first pad portion, and a first connection portion connecting the first pad portion and the second pad portion; a first probing pad connected to the first pad portion through first test contacts disposed on the first pad portion; and a second probing pad connected to the second pad portion through second test contacts disposed on the second pad portion.

Embodiments of the present disclosure may provide a semiconductor device comprising: a first semiconductor structure including a first surface and a second surface located opposite to the first surface in a direction perpendicular to the first surface; and a second semiconductor structure bonded to the first semiconductor structure, and including a third surface in contact with the second surface of the first semiconductor structure and a fourth surface located opposite to the third surface in a direction perpendicular to the third surface. The second semiconductor structure may include: a first test pad disposed on the third surface and including a first pad portion, a second pad portion spaced apart from the first pad portion, and a first connection portion connecting the first pad portion and the second pad portion; a first probing pad disposed on the fourth surface and connected to the first pad portion through first test contacts disposed on the first pad portion; and a second probing pad disposed on the fourth surface and connected to the second pad portion through second test contacts disposed on the second pad portion.

Embodiments of the present disclosure may provide a method for detecting a bonding defect in a semiconductor device including a first bonding pad on a substrate, a second bonding pad bonded to the first bonding pad, and a first test pad disposed on the same layer as the second bonding pad and having a first pad portion and a second pad portion spaced apart from each other. The method may include: applying a first voltage to a first probing pad connected to the first pad portion; applying a second voltage to a second probing pad connected to the second pad portion, the second voltage different from the first voltage; and determining whether a bonding defect has occurred by calculating a first sheet resistance value of the first test pad based on a current value between the first probing pad and the second probing pad.

According to embodiments of the present disclosure, it may be possible to provide a semiconductor device and a method for detecting a bonding defect in the semiconductor device, which may detect a defect occurring at a bonding interface.

The effects of embodiments of the present disclosure are not limited to those described above, and other effects not mentioned will be clearly understood by those skilled in the art from the description of the claims.

### BRIEF DESCRIPTION OF THE DRAWINGS

The present disclosure will be more fully understood from the following detailed description and the accompanying drawings. The detailed description and drawings are provided only for illustrative purposes and are not intended to limit the scope of the present disclosure.

FIG. 1 is a diagram illustrating an example of a planar structure of a semiconductor device according to embodiments of the present disclosure.

FIG. 2 is a diagram illustrating an example of a cross-sectional structure taken along line I-I′ of FIG. 1.

FIG. 3 is an enlarged view of region 10 in FIG. 2, showing an example of a bonding defect.

FIG. 4 to FIG. 7 are diagrams illustrating a process in which a bonding defect occurs.

FIG. 8 and FIG. 9 are diagrams illustrating other examples of cross-sectional structures taken along line I-I′ of FIG. 1.

FIG. 10 is a diagram illustrating another example of a planar structure of a semiconductor device according to embodiments of the present disclosure.

FIG. 11 is a diagram illustrating examples of cross sections taken along lines I-I′ and II-II′ of FIG. 10.

FIG. 12 to FIG. 14 are diagrams illustrating other examples of the cross sections taken along lines I-I′ and II-II′ of FIG. 10.

FIG. 15 to FIG. 18 are diagrams illustrating examples of a method for detecting a bonding defect in a semiconductor device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the accompanying drawings, two directions on a top surface of substrate 200 are defined as a first direction FD and a second direction SD, respectively, and a direction protruding perpendicularly from the top surface of substrate 200 is defined as a third direction VD. The first direction FD and the second direction SD may be substantially perpendicular to each other. The third direction VD is a direction perpendicular to both the first direction FD and the second direction SD. In the following specification, the term “perpendicular” or “perpendicular direction” will be used to mean substantially the same as the third direction VD. A direction indicated by an arrow in the drawings and its opposite direction represent the same direction.

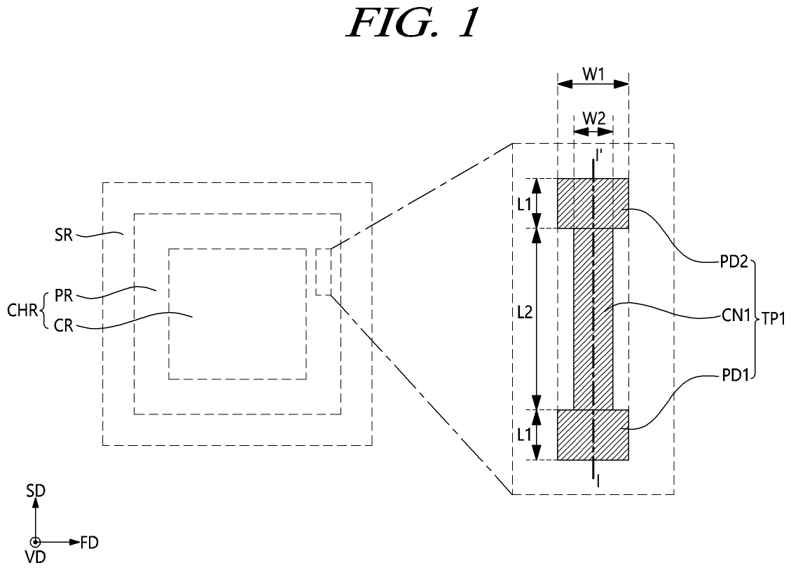

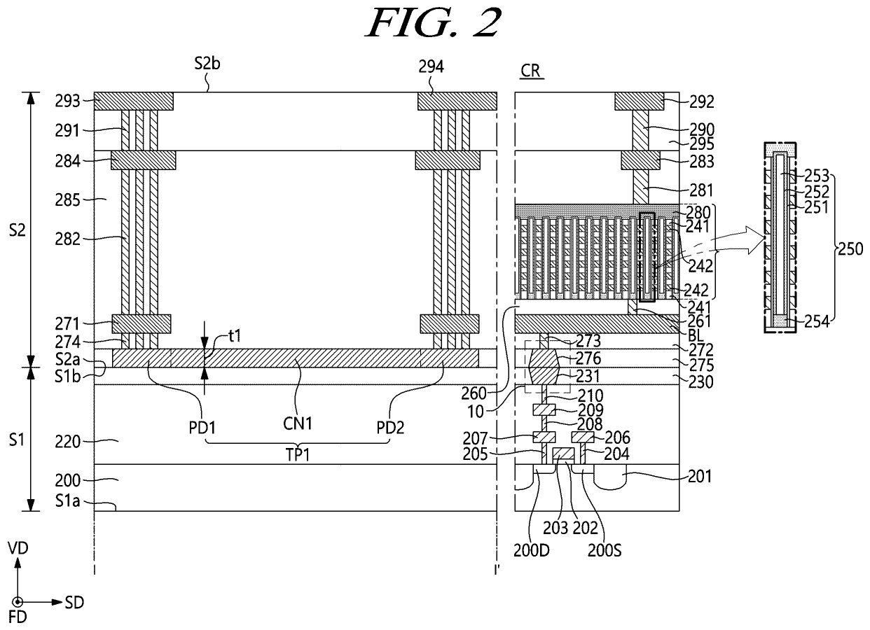

FIG. 1 is a diagram illustrating an example of a planar structure of a semiconductor device according to embodiments of the present disclosure. FIG. 2 is a diagram illustrating an example of a cross-sectional structure taken along line I-I′ of FIG. 1.

Referring to FIG. 1, the semiconductor device according to embodiments of the present disclosure may include a chip region CHR and a scribe lane region SR. The chip region CHR may refer to a region where various elements and circuits that constitute a single semiconductor device (or chip) are included. The scribe lane region SR may refer to a region located outside the chip region CHR, where various keys or test patterns are arranged. The scribe lane region SR may surround the chip region CHR.

The chip region CHR may include a cell region CR and a periphery region PR. The cell region CR may refer to a region where memory cells are arranged. The periphery region PR may refer to a region located outside the cell region CR, where circuits for supplying various voltages or signals to the memory cells are arranged. The periphery region PR may be located around the cell region CR.

In one embodiment, a first test pad TP1 may be disposed in the periphery region PR. The first test pad TP1 may be part of a test pattern for verifying whether the completed semiconductor device is operating properly. Alternatively, the first test pad TP1 may be part of a test pattern for detecting defects, such as signal failures, within the semiconductor device. In embodiments of the present disclosure, the first test pad TP1 may be a pattern for detecting bonding defects occurring in bonding pads.

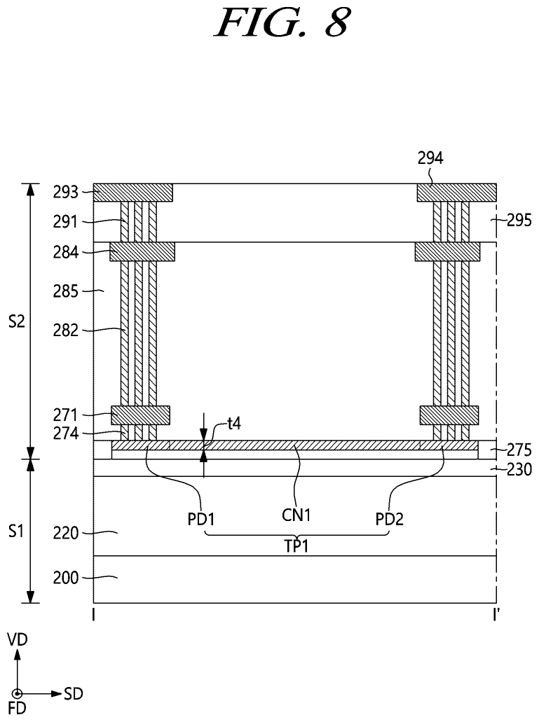

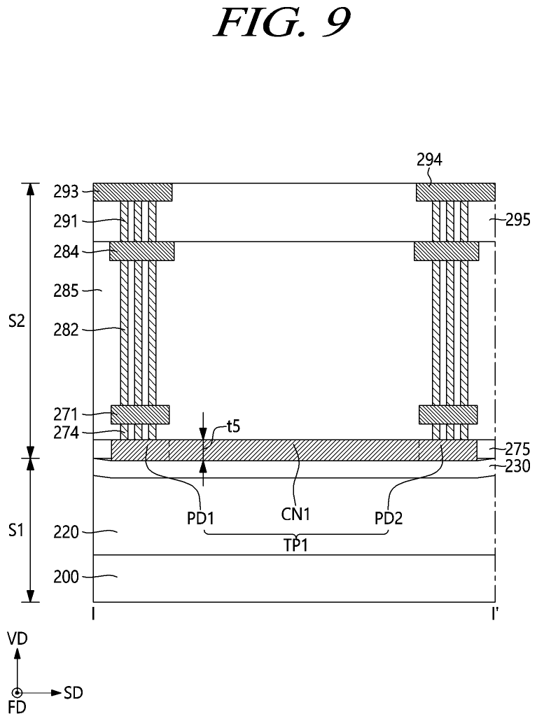

In one embodiment, a voltage supplied from outside the semiconductor device may be applied to the first test pad TP1. When a voltage is applied to the first test pad TP1, a resistance of the first test pad TP1 may be measured based on a current value flowing through the first test pad TP1. In one embodiment, the resistance of the first test pad TP1 may vary depending on whether a bonding defect has occurred. This will be described later with reference to FIG. 8 and FIG. 9.

Although FIG. 1 illustrates an example in which the first test pad TP1 is disposed in the periphery region PR, it is not limited thereto. The first test pad TP1 may also be disposed in the cell region CR or the scribe lane region SR.

The first test pad TP1 may include a first pad portion PD1, a second pad portion PD2, and a first connection portion CN1. The first pad portion PD1 and the second pad portion PD2 may be spaced apart from each other in the second direction SD. For example, the first pad portion PD1 and the second pad portion PD2 may be separate and/or not in contact with each other. Referring to FIG. 1 and FIG. 2, the first pad portion PD1 and the second pad portion PD2 may respectively refer to regions of the first test pad TP1 that are connected to a first probing pad 293 and a second probing pad 294. In one embodiment, a width W1 of the first pad portion PD1 in the first direction FD may be greater than a width W2 of the first connection portion CN1 in the first direction FD.

The first connection portion CN1 may connect the first pad portion PD1 and the second pad portion PD2. The first connection portion CN1 may be located between the first pad portion PD1 and the second pad portion PD2. In one embodiment, a length L2 of the first connection portion CN1 in the second direction SD may be greater than a length W2 of the first connection portion CN1 in the first direction FD.

In one embodiment, an area of a top surface of the first connection portion CN1, that is, a value obtained by multiplying the length W2 in the first direction FD and the length L2 in the second direction SD, may be greater than an area of a top surface of the first pad portion PD1, that is, a value obtained by multiplying the length W1 in the first direction FD and the length L1 in the second direction SD.

Referring to FIG. 2, the semiconductor device according to embodiments of the present disclosure may include a first semiconductor structure S1 and a second semiconductor structure S2. The first semiconductor structure S1 may include a first surface S1a and a second surface S1b located opposite to each other in a vertical direction VD. The second semiconductor structure S2 may include a third surface S2a and a fourth surface S2b located opposite to each other in the vertical direction. The third surface S2a of the second semiconductor structure S2 may be in contact with the second surface S1b of the first semiconductor structure S1.

The first semiconductor structure S1 may include a substrate 200, a device isolation layer 201, a source region 200S, a drain region 200D, a gate insulation layer 202, a gate electrode 203, a source contact 204, a drain contact 205, a first wiring 206, a second wiring 207, a first contact 208, a third wiring 209, a first bonding contact 210, a first insulation layer 220, a first bonding insulation layer 230, and a first bonding pad 231.

The second semiconductor structure S2 may include an insulation pattern 241, an electrode layer 242, a channel structure 250, a first interlayer insulation layer 260, a bit line contact 261, a bit line BL, a first test wiring 271, a second interlayer insulation layer 272, a second bonding contact 273, a first test contact 274, a second bonding insulation layer 275, a second bonding pad 276, the first test pad TP1, a source plate 280, a second contact 281, a second test contact 282, a fourth wiring 283, a second test wiring 284, a second insulation layer 285, a third contact 290, a third test contact 291, a fifth wiring 292, the first probing pad 293, the second probing pad 294, and a third insulation layer 295.

The channel structure 250 may include a charge storage pattern 251, a channel pattern 252, a core insulation layer 253, and a drain pad 254. In one embodiment, the charge storage pattern 251 may include a tunnel insulation layer, a charge trap layer, and a blocking layer. The tunnel insulation layer, the charge trap layer, and the blocking layer may be sequentially located on an outer surface of the channel pattern 252.

The channel structure 250, the insulation pattern 241, and the electrode layer 242 may constitute a NAND memory cell array. However, the semiconductor device according to embodiments of the present disclosure is not limited to a semiconductor device including a NAND memory cell array and may include any type of semiconductor device stacked through wafer bonding. In the following description, a semiconductor device including a NAND memory cell array will be described by way of example.

In the cell region CR, one channel structure 250 may be connected to one bit line BL through the bit line contact 261. The first test wiring 271 may be disposed on the same layer as the bit line BL. In one embodiment, the first test wiring 271 may be formed in the same process step as the bit line BL. The first test wiring 271 and the bit line BL may include a conductive material such as a metal, metal oxide, metal nitride, metal silicide, polysilicon, conductive carbon, or a combination thereof.

Below the bit line BL and the first test wiring 271, the second bonding contact 273 and the first test contact 274 may be respectively disposed. The second bonding contact 273 may connect the bit line BL and the second bonding pad 276. The first test contact 274 may connect the first test wiring 271 and the first test pad TP1. Although FIG. 2 illustrates three first test contacts 274, this is merely an example, and the number of first test contacts 274 may be numerous. In one embodiment, when the number of first test contacts 274 is sufficiently large, the resistance of the first test contacts 274 may be negligible. Referring to FIG. 1 and FIG. 2, the first test contact 274 may be connected to the first pad portion PD1 and the second pad portion PD2. The second bonding contact 273 and the first test contact 274 may include a conductive material such as a metal, metal oxide, metal nitride, metal silicide, polysilicon, conductive carbon, or a combination thereof.

Below the second bonding contact 273 and the first test contact 274, the first bonding pad 231 and the first test pad TP1 may be respectively disposed. The first test pad TP1 may be disposed on the same layer as the second bonding pad 276. For example, the first test pad TP1 and the second bonding pad 276 may be disposed on a third surface S2a of the second semiconductor structure S2. The second bonding insulation layer 275 may surround side surfaces of the first test pad TP1 and the second bonding pad 276.

In one embodiment, the first test pad TP1 and the second bonding pad 276 may be formed in the same process step. For example, the first test pad TP1 may include the same material as that forming the second bonding pad 276. The first test pad TP1 and the second bonding pad 276 may include copper (Cu), tantalum (Ta), tantalum nitride (TaN), manganese (Mn), or a combination thereof.

A bottom surface of the first test pad TP1 may be in substantially the same plane as a bottom surface of the second bonding pad 276. The bottom surface of the first test pad TP1 may be in contact with a top surface of the first bonding insulation layer 230. In one embodiment, the bottom surface of the first test pad TP1 may be in substantially the same plane as a bottom surface of the second bonding insulation layer 275.

The second semiconductor structure S2 may be bonded on the first semiconductor structure S1 through the first bonding pad 231, the second bonding pad 276, the first bonding insulation layer 230, and the second bonding insulation layer 275. For example, the first bonding pad 231 and the second bonding pad 276 may be bonded to each other. The first bonding insulation layer 230 and the second bonding insulation layer 275 may be bonded to each other. The first bonding insulation layer 230 may surround a side surface of the first bonding pad 231.

In the cell region CR, one channel structure 250 may be connected to the drain region 200D of a transistor through the bit line contact 261, the bit line BL, the second bonding contact 273, the second bonding pad 276, the first bonding pad 231, the first bonding contact 210, the third wiring 209, the first contact 208, the second wiring 207, and the drain contact 205.

The second test contact 282, the second test wiring 284, and the third test contact 291 may be sequentially disposed on the first test wiring 271. Although FIG. 2 illustrates three second test contacts 282 and three third test contacts 291, this is merely by way of example, and the number of second test contacts 282 and third test contacts 291 may be numerous. The second test contact 282 and the third test contact 291 may include the same material as the first test contact 274. The second test wiring 284 may include the same material as the first test wiring 271.

The first probing pad 293 and the second probing pad 294 may be disposed on the third test contact 291. The first probing pad 293 and the second probing pad 294 may be disposed on a fourth surface S2b of the second semiconductor structure S2. The first probing pad 293 and the second probing pad 294 may be connected to the first test pad TP1 through the third test contact 291, the second test wiring 284, the second test contact 282, the first test wiring 271, and the first test contact 274.

A voltage supplied from outside the semiconductor device may be applied to the first probing pad 293 and the second probing pad 294. A voltage applied to the first probing pad 293 may be different from a voltage applied to the second probing pad 294. For example, a ground voltage (0V) may be applied to the first probing pad 293, and a voltage equal to or greater than 0.1V may be applied to the second probing pad 294. Alternatively, a ground voltage may be applied to the second probing pad 294, and a voltage equal to or greater than 0.1V may be applied to the first probing pad 293.

The first probing pad 293 and the second probing pad 294 may include a conductive material such as a metal, metal oxide, metal nitride, metal silicide, polysilicon, conductive carbon, or a combination thereof.

In one embodiment, when no bonding defect occurs, a bottom surface of the second bonding pad 276 may be in full contact with a top surface of the first bonding pad 231. However, when a bonding defect occurs, the bottom surface of the second bonding pad 276 may be spaced apart from the top surface of the first bonding pad 231. Alternatively, when a bonding defect occurs, at least a portion of the second bonding insulation layer 275 may be spaced apart from the first bonding insulation layer 230.

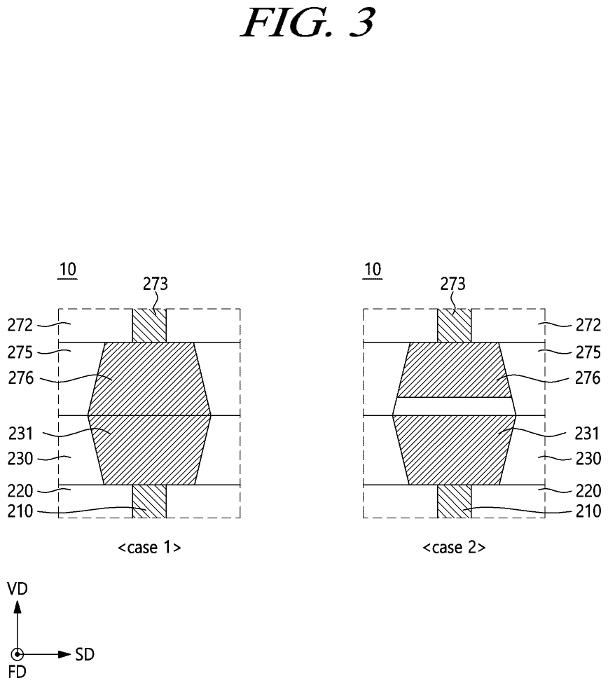

FIG. 3 is an enlarged view of region 10 of FIG. 2, illustrating an example of a bonding defect. FIG. 3 shows a case in which bonding is normally formed (case 1) and a case in which a bonding defect occurs (case 2).

A bonding defect may include a bonding defect between the first bonding pad 231 and the second bonding pad 276, a bonding defect between the first bonding insulation layer 230 and the second bonding insulation layer 275, or a combination thereof. For example, a bonding defect may include a defect caused by excessive dishing of a top surface of the first bonding pad 231 or the second bonding pad 276 during a formation process thereof. Alternatively, the bonding defect may include a defect caused by slight dishing on a top surface of the first bonding pad 231 or the second bonding pad 276 or a defect inherently formed in the first bonding pad 231 or the second bonding pad 276.

Hereinafter, a defect caused by excessive etching (dishing) of a top surface of the first bonding pad 231 or the second bonding pad 276 will be described as an example.

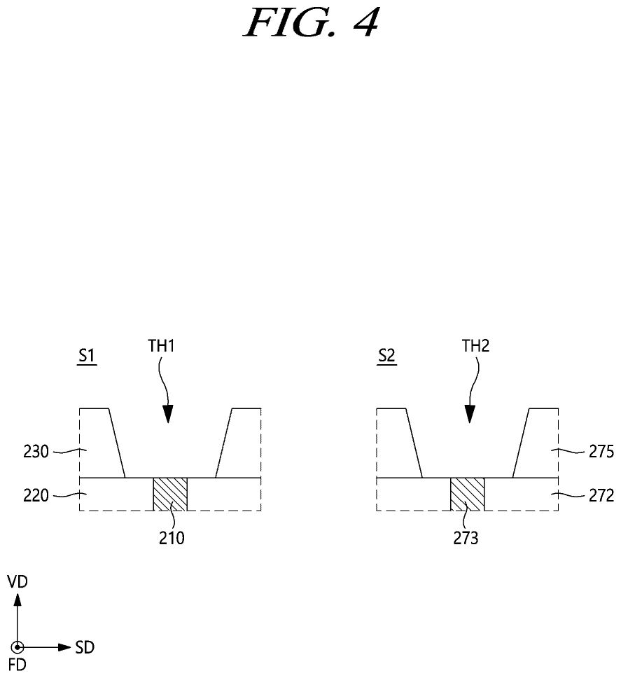

Referring to FIG. 3, when bonding is properly performed between the first bonding pad 231 and the second bonding pad 276 as shown in case 1, a bottom surface of the second bonding pad 276 may be in full contact with a top surface of the first bonding pad 231. However, as shown in case 2, when a top surface of the second bonding pad 276 is excessively dished, the bottom surface of the second bonding pad 276 may be spaced apart from the top surface of the first bonding pad 231. Hereinafter, the phenomenon in which dishing occurs excessively will be described in detail with reference to FIG. 4 to FIG. 7.

FIG. 4 to FIG. 7 are diagrams illustrating a process in which a bonding defect occurs. FIG. 4 to FIG. 7 illustrate the formation processes of the first bonding pad 231 and the second bonding pad 276 in case 2 of FIG. 3.

Referring to FIG. 4, the first bonding insulation layer 230 may be formed on the first insulation layer 220 and the first bonding contact 210 included in the first semiconductor structure S1. A first trench TH1 may be formed in the first bonding insulation layer 230. The second bonding insulation layer 275 may be formed on the second interlayer insulation layer 272 and the second bonding contact 273 included in the second semiconductor structure S2. A second trench TH2 may be formed in the second bonding insulation layer 275.

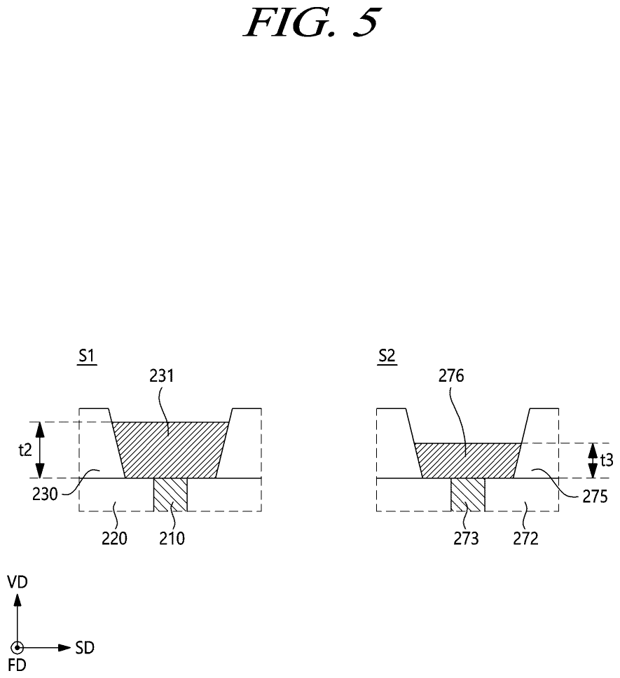

Referring to FIG. 5, the first bonding pad 231 and the second bonding pad 276 may be respectively formed in the first trench TH1 and the second trench TH2.

A process for forming the first bonding pad 231 and the second bonding pad 276 may include depositing a conductive material in the first trench TH1 and the second trench TH2, and then removing an upper portion of the conductive material through a grinding or chemical mechanical polishing (CMP) process. The conductive material may include copper (Cu), tantalum (Ta), tantalum nitride (TaN), or a combination thereof.

In some embodiments, the conductive material deposited in the second trench TH2 may be removed more than the conductive material deposited in the first trench TH1. For example, excessive dishing may occur in the conductive material deposited in the second trench TH2. Accordingly, a vertical thickness t2 of the first bonding pad 231 may be greater than a vertical thickness t3 of the second bonding pad 276.

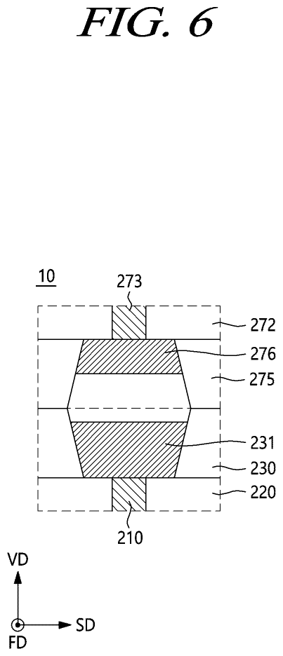

Referring to FIG. 6, the second semiconductor structure S2 may be stacked on the first semiconductor structure S1. The second bonding insulation layer 275 may be stacked on the first bonding insulation layer 230. The second bonding pad 276 may be spaced apart from the first bonding pad 231.

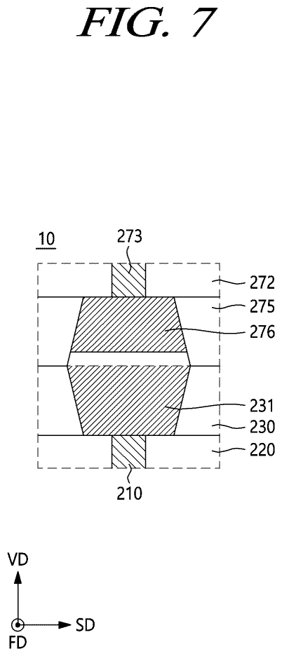

Referring to FIG. 7, a heating process may be performed on the first bonding pad 231 and the second bonding pad 276. The heated first bonding pad 231 and second bonding pad 276 may expand. A top surface of the expanded first bonding pad 231 may be in substantially the same plane as a top surface of the first bonding insulation layer 230.

However, a bottom surface of the expanded second bonding pad 276 may be positioned higher than a bottom surface of the second bonding insulation layer 275. The second bonding pad 276 may be spaced apart from the first bonding pad 231. The second bonding pad 276 and the first bonding pad 231 may be physically and electrically separated. That is, due to excessive dishing, a bonding defect may occur in the second bonding pad 276.

Referring again to FIG. 2, when a bonding defect occurs and the second bonding pad 276 is separated from the first bonding pad 231, the channel structure 250 included in the second semiconductor structure S2 may not be electrically connected to the transistor included in the first semiconductor structure S1. In other words, electrical connection between the first semiconductor structure S1 and the second semiconductor structure S2 may not be properly established. Accordingly, the semiconductor device may not function properly.

According to an embodiment of the present disclosure, a bonding defect between the first bonding pad 231 and the second bonding pad 276 may be detected in advance because the first test pad TP1, test contacts 274, 282, and 291, test wirings 271 and 284, the first probing pad 293, and the second probing pad 294 are disposed within the second semiconductor structure S2.

Referring again to FIG. 1 and FIG. 2, the first test pad TP1 may be formed in the same process step as the second bonding pad 276. That is, when no bonding defect as described with reference to FIG. 4 to FIG. 7 occurs in the second bonding pad 276, a bottom surface of the first test pad TP1 may be in substantially the same plane as a bottom surface of the second bonding insulation layer 275. In addition, the bottom surface of the first test pad TP1 may be in full contact with a top surface of the first bonding insulation layer 230.

When a bonding defect occurs, a vertical thickness of the first test pad TP1 may differ from a vertical thickness t1 of the first test pad TP1 in the case where no bonding defect occurs. When the thickness of the first test pad TP1 changes, the sheet resistance of the first test pad TP1 may vary as expressed by Equation 1 below.

Rs=ρ/t [Equation 1]

In Equation 1, Rs denotes the sheet resistance, ρ denotes the resistivity, and t denotes the vertical thickness of the object.

Because ρ is an intrinsic property of the material, when a bonding defect such as dishing occurs and the thickness of the first test pad TP1 is reduced, the sheet resistance of the first test pad TP1 changes accordingly.

In an embodiment of the present disclosure, the occurrence of a bonding defect may be detected by comparing the sheet resistance of the first test pad TP1 in the case where a bonding defect has occurred with the sheet resistance of the first test pad TP1 in the case where no bonding defect has occurred.

The sheet resistance of the first test pad TP1 in the case where no bonding defect has occurred may correspond to the sheet resistance when the entire bottom surface of the first test pad TP1 is in the same plane as the bottom surface of the second bonding insulation layer 275. The vertical thickness t1 of the first test pad TP1 in the case where no bonding defect has occurred may be substantially the same as the vertical thickness of the second bonding insulation layer 275. Accordingly, if the vertical thickness of the second bonding insulation layer 275 is known, the sheet resistance of the first test pad TP1 may be calculated using Equation 1.

In one embodiment, during the manufacturing of the semiconductor device, the second bonding insulation layer 275 may be formed to have a predetermined thickness. Accordingly, referring to Equation 1, the sheet resistance of the first test pad TP1 in the case where no bonding defect has occurred may be a value obtained by dividing the resistivity of the material forming the first test pad TP1 by the predetermined thickness of the second bonding insulation layer 275.

Hereinafter, the sheet resistance of the first test pad TP1 in the case where no bonding defect has occurred will be referred to as a first reference value.

Once the first reference value is obtained, the sheet resistance of the first test pad TP1 included in an arbitrary semiconductor device, in which the presence of a bonding defect is unknown, may be measured and compared to the first reference value. By comparing the measured sheet resistance of the first test pad TP1 with the first reference value, it may be determined whether a bonding defect has occurred. This will be described in more detail with reference to FIG. 8 and FIG. 9.

FIG. 8 and FIG. 9 are diagrams illustrating other examples of cross-sectional structures taken along line I-I′ of FIG. 1.

Referring to FIG. 8, the first test pad TP1 may be formed in the same process step as the second bonding pad 276 in FIG. 2. When excessive dishing occurs in the second bonding pad 276 as in case 2 of FIG. 3, a bonding defect may also occur in the first test pad TP1, as illustrated in FIG. 8. A vertical thickness t4 of the first test pad TP1 may be less than the vertical thickness t1 of the first test pad TP1 in FIG. 2.

As described above, different voltages may be applied between the first probing pad 293 and the second probing pad 294, and the current between the first probing pad 293 and the second probing pad 294 may be measured. Based on this, the resistance between the first probing pad 293 and the second probing pad 294 may be calculated. Once the resistance between the first and second probing pads 293 and 294 is calculated, the sheet resistance of the first test pad TP1 included in the arbitrary semiconductor device may be calculated based on Equation 1 and the following Equation 2.

R=Rs×L/W [Equation 2]

In Equation 2, R denotes the resistance of the first test pad TP1, Rs denotes the sheet resistance of the first test pad TP1, L denotes a length of the first test pad TP1 in the second direction SD, and W denotes a width of the first test pad TP1 in the first direction FD.

Because the values of L and W are predetermined, the sheet resistance of the first test pad TP1 may be calculated by measuring the resistance of the first test pad TP1 included in an arbitrary semiconductor device.

The resistance of the first test pad TP1 may be calculated from a current flowing between the first probing pad 293 and the second probing pad 294. This is explained in detail as follows.

For example, a positive voltage may be applied to the first probing pad 293, and a ground voltage may be applied to the second probing pad 294. A current may flow from the first probing pad 293 to the second probing pad 294 along test contacts, test wirings, and the first test pad TP1. In this case, a resistance between the first probing pad 293 and the second probing pad 294 may be a value obtained by summing, in series, the resistances of the test contacts 274, 282, and 291, the test wirings 271 and 284, and the first test pad TP1, and contact resistances between the test contacts and the test wirings.

As described above with reference to FIG. 2, the number of the test contacts 274, 282, and 291 may be numerous, and the test contacts 274, 282, and 291 and the test wirings 271 and 284 may include the same material. In this case, the resistance of the test contacts 274, 282, and 291, and the contact resistance between the test contacts 274, 282, and 291 and the test wirings 271 and 284 may be small. In addition, a length of the first connection portion CN1 of the first test pad TP1 may be very large. In one embodiment, a length L2 of the first connection portion CN1 in the second direction SD may be more than 100 times greater than a length of the first pad portion PD1 or the second pad portion PD2 in the second direction SD. In such a case, the resistance measured between the first and second probing pads 293 and 294 may be considered to be substantially the same as the resistance of the first test pad TP1.

Accordingly, by measuring the current flowing between the first probing pad 293 and the second probing pad 294, the resistance of the first test pad TP1 may be calculated.

If excessive dishing occurs in the first test pad TP1, the resistance of the first test pad TP1 will be measured to be large. Accordingly, based on Equation 2, the sheet resistance of the first test pad TP1 may be calculated to be greater than the first reference value. In one embodiment, when the calculated sheet resistance of the first test pad TP1 exceeds 105% of the first reference value, it may be determined that a bonding defect has occurred in the second bonding pad 276 of FIG. 2.

Accordingly, even in instances in which the thickness of the first bonding pad 231 or the second bonding pad 276 is unknown, a bonding defect may be detected by measuring the current between the first probing pad 293 and the second probing pad 294.

Referring to FIG. 9, different voltages may be applied between the first probing pad 293 and the second probing pad 294 to measure the current therebetween. Once the current between the first and second probing pads 293 and 294 is measured, the sheet resistance of the first test pad TP1 may be calculated based on Equation 1 and Equation 2 as described above.

A bonding defect may also occur when dishing is insufficient, as illustrated in FIG. 9. Referring to FIG. 5 and FIG. 6, when dishing during the formation of the bonding pad is minimal, the second bonding pad 276 may have a thickness greater than t2. In this case, when heat is applied during a subsequent process, the second bonding pad 276 may expand to have a thickness greater than the second bonding insulation layer 275. Because the first test pad TP1 may have the same thickness as the second bonding pad 276, a vertical thickness t5 of the first test pad TP1 shown in FIG. 9 may be greater than a vertical thickness t1 (for example, an optimal vertical thickness) of the first test pad TP1 shown in FIG. 2.

If significantly less dishing occurs on the first test pad TP1, the resistance of the first test pad TP1 will be measured to be small. Accordingly, the sheet resistance of the first test pad TP1 may be calculated to be smaller than the first reference value. In one embodiment, when the sheet resistance of the first test pad TP1 is less than 95% of the first reference value, it may be determined that a bonding defect has occurred in the second bonding pad 276 of FIG. 2.

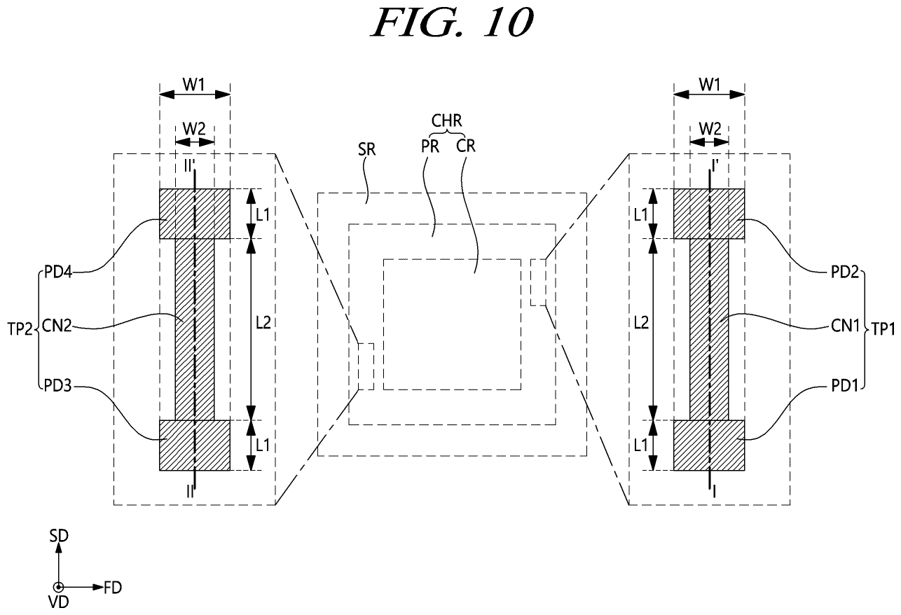

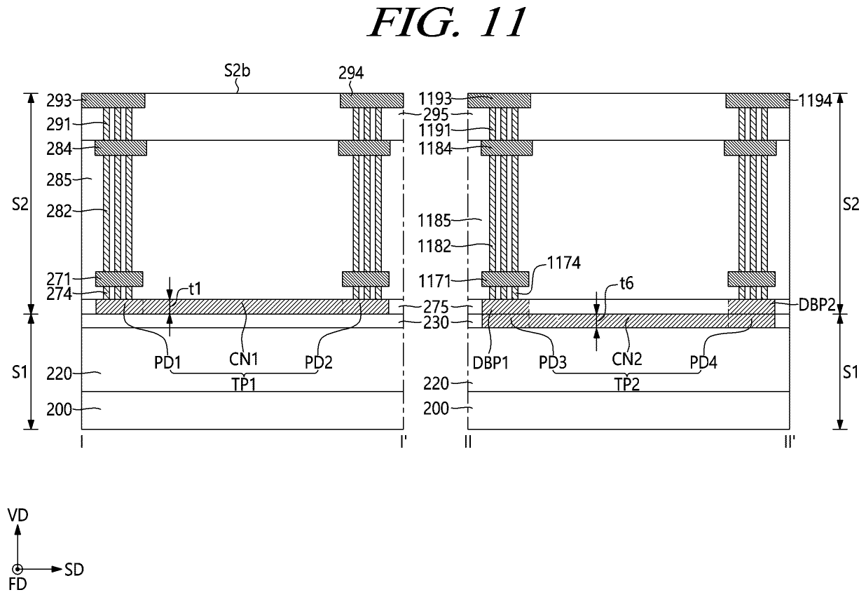

FIG. 10 is a diagram illustrating another example of a planar structure of a semiconductor device according to embodiments of the present disclosure. FIG. 11 is a diagram illustrating examples of cross sections taken along lines I-I′ and II-II′ of FIG. 10.

Referring to FIG. 10, a first test pad TP1 and a second test pad TP2 may be disposed in the periphery region PR. In an embodiment of the present disclosure, the first test pad TP1 and the second test pad TP2 may be patterns for detecting bonding defects occurring in bonding pads. The first test pad TP1 may be substantially the same as the first test pad TP1 described above with reference to FIG. 1.

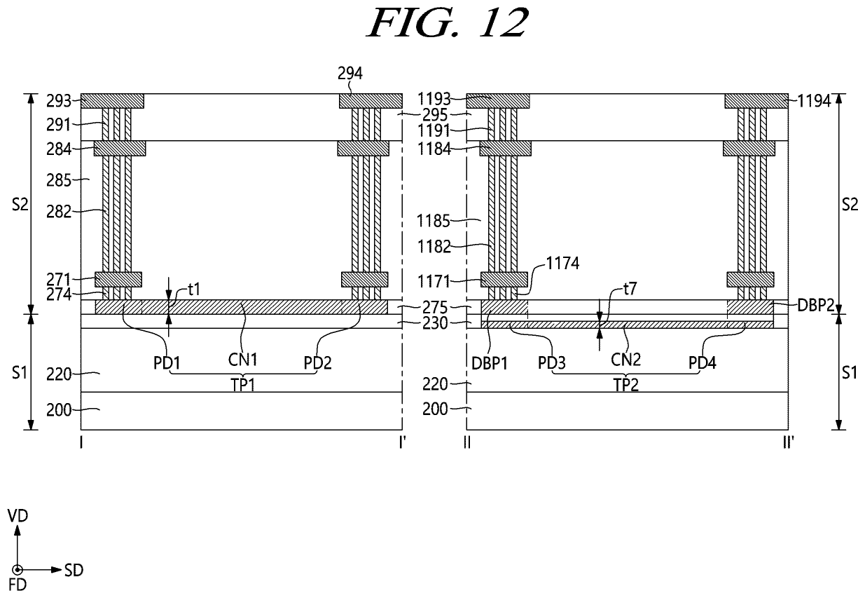

In one embodiment, voltages supplied from outside the semiconductor device may be applied to the first test pad TP1 and the second test pad TP2. When voltages are applied to the first and second test pads TP1 and TP2, the resistances of the first and second test pads TP1 and TP2 may be measured from the respective current values flowing through them. In one embodiment, the resistances of the first and second test pads TP1 and TP2 may vary depending on whether a bonding defect has occurred. This will be described later with reference to FIG. 12 to FIG. 14.

Although FIG. 10 illustrates the first and second test pads TP1 and TP2 as being disposed in the periphery region PR, the present disclosure is not limited thereto. At least one of the first and second test pads TP1 and TP2 may be disposed in the cell region CR or the scribe lane region SR.

The second test pad TP2 may include a third pad portion PD3, a fourth pad portion PD4, and a second connection portion CN2. The third pad portion PD3 and the fourth pad portion PD4 may be spaced apart from each other in the second direction SD. Referring to FIG. 10 and FIG. 11, the third pad portion PD3 and the fourth pad portion PD4 may respectively refer to regions of the second test pad TP2 that are connected to a third probing pad 1193 and a fourth probing pad 1194. In one embodiment, a width of the second pad portion PD2 in the first direction FD may be greater than a width of the second connection portion CN2 in the first direction FD.

The second connection portion CN2 may connect the third pad portion PD3 and the fourth pad portion PD4. The second connection portion CN2 may be located between the third pad portion PD3 and the fourth pad portion PD4. In one embodiment, a length of the second connection portion CN2 in the second direction SD may be greater than a length W2 of the second connection portion CN2 in the first direction FD.

In one embodiment, an area of a top surface of the second connection portion CN2, that is, a value obtained by multiplying the length W2 in the first direction FD by the length L2 in the second direction SD, may be greater than an area of a top surface of the third pad portion PD3, which is calculated by multiplying the length W1 in the first direction FD by the length L1 in the second direction SD.

Referring to FIG. 11, a semiconductor device according to embodiments of the present disclosure may include the first semiconductor structure S1 and the second semiconductor structure S2.

The first semiconductor structure S1 may include the substrate 200, the first insulation layer 220, the first bonding insulation layer 230, and the second test pad TP2.

The second test pad TP2 may be disposed on the first insulation layer 220. The second test pad TP2 may be disposed on the same layer as the first bonding pad 231 in FIG. 2. For example, the second test pad TP2 and the first bonding pad 231 may be disposed on a second surface S1b of the first semiconductor structure S1. The first bonding insulation layer 230 may surround a side surface of the second test pad TP2.

A bottom surface of the second test pad TP2 may be in substantially the same plane as a bottom surface of the first bonding insulation layer 230. A top surface of the second test pad TP2 may be in contact with a bottom surface of the second bonding insulation layer 275. In one embodiment, the top surface of the second test pad TP2 may be in substantially the same plane as a top surface of the first bonding insulation layer 230.

The second semiconductor structure S2 may include the first test wiring 271, a third test wiring 1171, the first test contact 274, a fourth test contact 1174, the second bonding insulation layer 275, the first test pad TP1, the first dummy bonding pad DBP1, a second dummy bonding pad DBP2, the second test contact 282, a fifth test contact 1182, the second test wiring 284, a fourth test wiring 1184, the second insulation layer 285, the third test contact 291, a sixth test contact 1191, the first probing pad 293, the second probing pad 294, the third probing pad 1193, the fourth probing pad 1194, and the third insulation layer 295.

The third test wiring 1171 may be disposed on the same layer as the first test wiring 271. In one embodiment, the third test wiring 1171 may be formed in the same process step as the first test wiring 271. The third test wiring 1171 may include a conductive material such as a metal, metal oxide, metal nitride, metal silicide, polysilicon, conductive carbon, or a combination thereof.

The fourth test contact 1174 may be disposed under the third test wiring 1171. The fourth test contact 1174 may connect the third test wiring 1171 and the first dummy bonding pad DBP1. Although FIG. 11 illustrates three fourth test contacts 1174, this is merely by way of example, and the number of fourth test contacts 1174 may be numerous. Referring to FIG. 10 and FIG. 11, the fourth test contact 1174 may be connected to the first dummy bonding pad DBP1 and the second dummy bonding pad DBP2. The fourth test contact 1174 may include a conductive material such as a metal, metal oxide, metal nitride, metal silicide, polysilicon, conductive carbon, or a combination thereof.

The first dummy bonding pad DBP1 and the second dummy bonding pad DBP2 may be disposed under the fourth test contact 1174. The first and second dummy bonding pads DBP1 and DBP2 may be disposed on the same layer as the first test pad TP1. For example, the second bonding insulation layer 275 may surround side surfaces of the first dummy bonding pad DBP1 and the second dummy bonding pad DBP2.

In one embodiment, the first dummy bonding pad DBP1 and the second dummy bonding pad DBP2 may be formed in the same process step as the first test pad TP1. For example, the first dummy bonding pad DBP1 and the second dummy bonding pad DBP2 may include the same material as the first test pad TP1. The first and second dummy bonding pads DBP1 and DBP2 may include copper (Cu), tantalum (Ta), tantalum nitride (TaN), or a combination thereof.

A bottom surface of the first dummy bonding pad DBP1 and a bottom surface of the second dummy bonding pad DBP2 may be in substantially the same plane as a bottom surface of the first test pad TP1. The bottom surfaces of the first and second dummy bonding pads DBP1 and DBP2 may be in contact with a top surface of the second test pad TP2. In one embodiment, the bottom surfaces of the first and second dummy bonding pads DBP1 and DBP2 may be in substantially the same plane as a bottom surface of the second bonding insulation layer 275.

The second semiconductor structure S2 may be bonded to the first semiconductor structure S1.

The fifth test contact 1182, the fourth test wiring 1184, and the sixth test contact 1191 may be sequentially disposed on the third test wiring 1171. Although FIG. 11 illustrates three fifth test contacts 1182 and three sixth test contacts 1191, this is merely by way of example, and the number of fifth and sixth test contacts may be numerous. The fifth test contact 1182 and the sixth test contact 1191 may include the same material as the fourth test contact 1174. The fourth test wiring 1184 may include the same material as the third test wiring 1171.

A third probing pad 1193 and a fourth probing pad 1194 may be disposed on the sixth test contact 1191. Referring to FIG. 2 and FIG. 11, the third probing pad 1193 and the fourth probing pad 1194 may be disposed on a fourth surface S2b of the second semiconductor structure S2. The third and fourth probing pads 1193 and 1194 may be connected to the second test pad TP2 through the sixth test contact 1191, the fourth test wiring 1184, the fifth test contact 1182, the third test wiring 1171, the fourth test contact 1174, and the first and second dummy bonding pads DBP1 and DBP2.

Voltages supplied from outside the semiconductor device may be applied to the third probing pad 1193 and the fourth probing pad 1194. A voltage applied to the third probing pad 1193 may be different from a voltage applied to the fourth probing pad 1194 (for example, by a predetermined minimum difference). For example, a ground voltage may be applied to the third probing pad 1193, and a voltage equal to or greater than 0.1V may be applied to the fourth probing pad 1194. Alternatively, a ground voltage may be applied to the fourth probing pad 1194, and a voltage equal to or greater than 0.1V may be applied to the third probing pad 1193.

The third probing pad 1193 and the fourth probing pad 1194 may include a conductive material such as a metal, metal oxide, metal nitride, metal silicide, polysilicon, conductive carbon, or a combination thereof.

In an embodiment of the present disclosure, the second test pad TP2 may be formed in the same process step as the first bonding pad 231 in FIG. 2. When no bonding defect, as described with reference to FIG. 4 to FIG. 7, occurs in the first bonding pad 231, a top surface of the second test pad TP2 may be in substantially the same plane as a top surface of the first bonding insulation layer 230. In addition, the top surface of the second test pad TP2 may be in contact with a bottom surface of the second bonding insulation layer 275.

A vertical thickness t6 of the second test pad TP2 in a case where no bonding defect occurs may be substantially the same as the vertical thickness of the first bonding insulation layer 230. Accordingly, if the vertical thickness of the first bonding insulation layer 230 is known, the sheet resistance of the second test pad TP2 may be calculated with reference to Equation 1.

In one embodiment, during the manufacturing of the semiconductor device, the first bonding insulation layer 230 may be formed to have a predetermined thickness. Accordingly, with reference to Equation 1, the sheet resistance of the second test pad TP2 in a case where no bonding defect occurs may be a value obtained by dividing the resistivity of the material forming the second test pad TP2 by the predetermined thickness of the first bonding insulation layer 230. Because the second test pad TP2 may have substantially the same thickness as the first test pad TP1, the sheet resistance of the second test pad TP2 in a case where no bonding defect occurs may be the first reference value.

Once the first reference value is obtained, the sheet resistance of the second test pad TP2 included in an arbitrary semiconductor device, where it is not known whether a bonding defect has occurred, may be measured and compared with the first reference value. By comparing the measured sheet resistance of the second test pad TP2 with the first reference value, whether a bonding defect has occurred may be determined. This will be described in detail with reference to FIG. 12 to FIG. 14.

FIG. 12 to FIG. 14 are diagrams illustrating other examples of cross-sectional structures taken along lines I-I′ and II-II′ of FIG. 10.

Referring to FIG. 12 to FIG. 14, the second test pad TP2 may be formed in the same process step as the first bonding pad 231 of FIG. 2. When excessive dishing occurs in the first bonding pad 231 of FIG. 2, a bonding defect may also occur in the second test pad TP2, as shown in FIG. 12.

Referring to FIG. 12, the second test pad TP2 may be spaced apart from the first dummy bonding pad DBP1 and the second dummy bonding pad DBP2. In this case, the third probing pad 1193 and the fourth probing pad 1194 may be electrically isolated. A vertical thickness t7 of the second test pad TP2 may be less than a vertical thickness t1 of the first test pad TP1.

As described above, different voltages may be applied between the third probing pad 1193 and the fourth probing pad 1194, and a current between the third probing pad 1193 and the fourth probing pad 1194 may be measured. Once the current between the third probing pad 1193 and the fourth probing pad 1194 is measured, the sheet resistance of the second test pad TP2 included in an arbitrary semiconductor device may be calculated based on Equations 1 and 2. Because the values of L and W are predetermined, the sheet resistance of the second test pad TP2 may be calculated by measuring the resistance of the second test pad TP2 included in an arbitrary semiconductor device.

The resistance of the second test pad TP2 may be calculated from the current flowing between the third probing pad 1193 and the fourth probing pad 1194. The method of calculating the resistance of the second test pad TP2 may be similar to the method of calculating the resistance of the first test pad TP1 described above. Because the first and second dummy bonding pads DBP1 and DBP2 may include the same material as the second test pad TP2, the contact resistance between the first and second dummy bonding pads DBP1 and DBP2 and the second test pad TP2 may be negligible.

When excessive dishing occurs in the second test pad TP2, the third probing pad 1193 and the fourth probing pad 1194 may be electrically isolated, resulting in a very low measured current. That is, the resistance of the second test pad TP2 may be measured to be very high. Accordingly, the sheet resistance of the second test pad TP2 may be greater than the first reference value. In one embodiment, when the calculated sheet resistance of the second test pad TP2 exceeds 105% of the first reference value, it may be determined that a bonding defect has occurred in the first bonding pad 231 of FIG. 2.

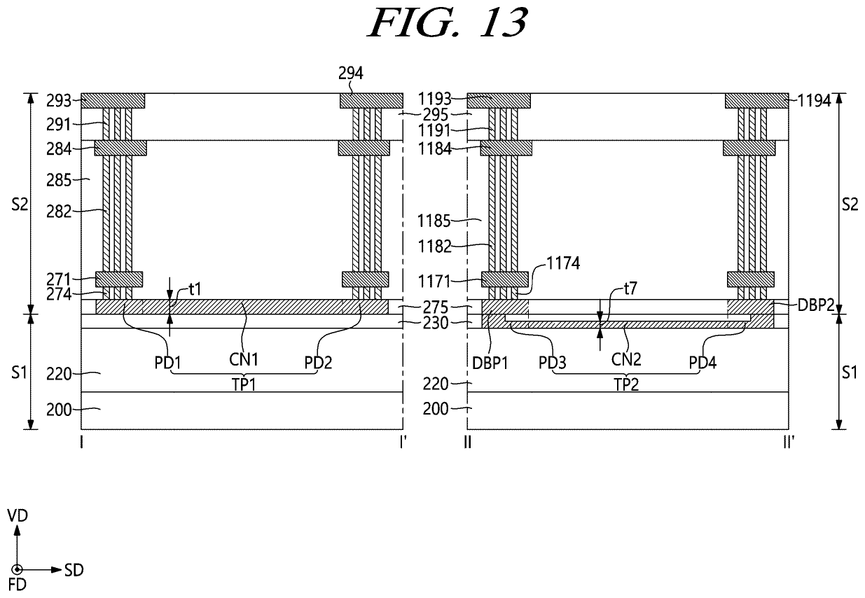

Referring to FIG. 13, the second test pad TP2 may be partially connected to the first dummy bonding pad DBP1 and the second dummy bonding pad DBP2. In this case, a current may flow between the third probing pad 1193 and the fourth probing pad 1194. The resistance of the second test pad TP2 may be calculated based on the current between the third probing pad 1193 and the fourth probing pad 1194.

When excessive dishing occurs on the second test pad TP2, its sheet resistance may be greater than the first reference value. In one embodiment, if the calculated sheet resistance of the second test pad TP2 exceeds 105% of the first reference value, it may be determined that a bonding defect has occurred in the first bonding pad 231 of FIG. 2.

Accordingly, even if the thicknesses of the first bonding pad 231 or the second bonding pad 276 of FIG. 2 are not known, bonding defects may still be detected by measuring the current between the third probing pad 1193 and the fourth probing pad 1194.

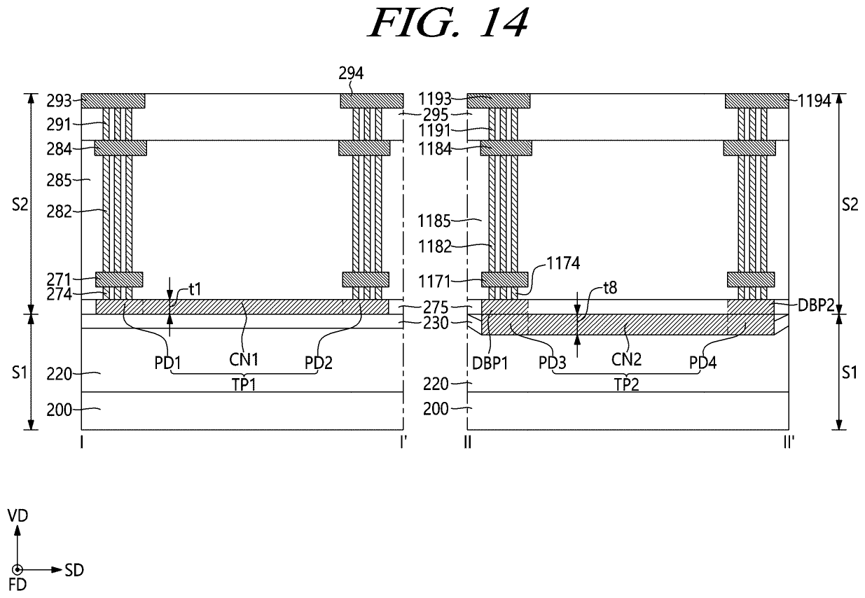

Referring to FIG. 14, different voltages may be applied between the third probing pad 1193 and the fourth probing pad 1194 to measure the current therebetween. Once the current between the third probing pad 1193 and the fourth probing pad 1194 is measured, the sheet resistance of the second test pad TP2 may be calculated based on Equations 1 and 2 as described above.

A bonding defect may also occur when dishing is insufficient, as illustrated in FIG. 14. Referring again to FIG. 5 and FIG. 6, if dishing is minimal during the formation of the bonding pad, the first bonding pad 231 may have a thickness greater than t2. In this case, when heat is applied in a subsequent process, the first bonding pad 231 may expand to a thickness greater than that of the first bonding insulation layer 230. Because the second test pad TP2 may have the same thickness as the first bonding pad 231, a vertical thickness t8 of the second test pad TP2 may be greater than a vertical thickness t1 of the first test pad TP1.

When dishing occurs very slightly in the second test pad TP2, its resistance may be measured to be low. Accordingly, the sheet resistance of the second test pad TP2 may be calculated to be less than the first reference value. If the sheet resistance of the second test pad TP2 is less than 95% of the first reference value, it may be determined that a bonding defect has occurred in the first bonding pad 231 of FIG. 2.

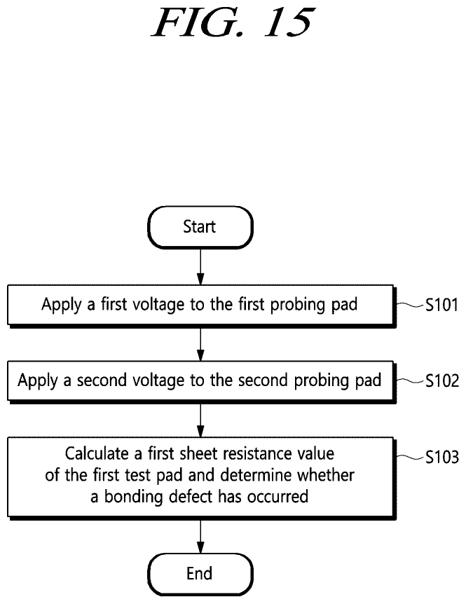

FIG. 15 to FIG. 18 are diagrams illustrating examples of methods for detecting bonding defects in semiconductor devices according to embodiments of the present disclosure.

Referring to FIG. 15, a bonding defect detection method for a semiconductor device according to embodiments of the present disclosure may include: applying a first voltage to the first probing pad 293 (S101); applying a second voltage to the second probing pad 294 (S102); and determining whether a bonding defect has occurred by calculating a first sheet resistance value of the first test pad TP1 (S103).

The bonding defect detection method illustrated in FIG. 15 may be applied to a semiconductor device described with reference to FIG. 1 and FIG. 2.

Referring to FIG. 1, FIG. 2, and FIG. 15, the semiconductor device may include the substrate 200; the first bonding pad 231 on the substrate 200; the second bonding pad 276 bonded to the first bonding pad 231; the first test pad TP1 disposed on the same layer as the second bonding pad 276 and including the first pad portion PD1 and the second pad portion PD2 spaced apart from each other; the first probing pad 293; and the second probing pad 294.

The first probing pad 293 may be connected to the first pad portion PD1, and the second probing pad 294 may be connected to the second pad portion PD2. A first voltage may be applied to the first probing pad 293, and a second voltage different from the first voltage may be applied to the second probing pad 294.

Referring to Equation 2, a first sheet resistance value of the first test pad TP1 may be calculated based on a current value between the first probing pad 293 and the second probing pad 294.

In one embodiment, if the first sheet resistance value differs from the first reference value, it may be determined that a bonding defect has occurred. The first reference value may be the sheet resistance of the first test pad TP1 when the entire bottom surface of the first test pad TP1 is in the same plane as the bottom surface of the second bonding insulation layer 275.

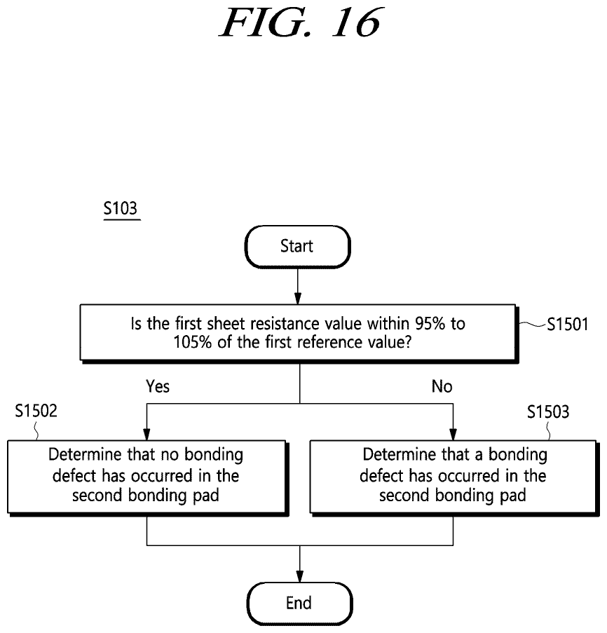

Referring to FIG. 16, the operation (S103) of determining whether a bonding defect has occurred by calculating the first sheet resistance value of the first test pad TP1 may further include determining whether the first sheet resistance value is within 95% to 105% of the first reference value (S1501).

If the first sheet resistance value is within the range of 95% to 105% of the first reference value (S1501, Yes), it may be determined that no bonding defect has occurred in the second bonding pad 276 (S1502). If the first sheet resistance value is less than 95% or greater than 105% of the first reference value (S1501, No), it may be determined that a bonding defect has occurred in the second bonding pad 276 (S1503).

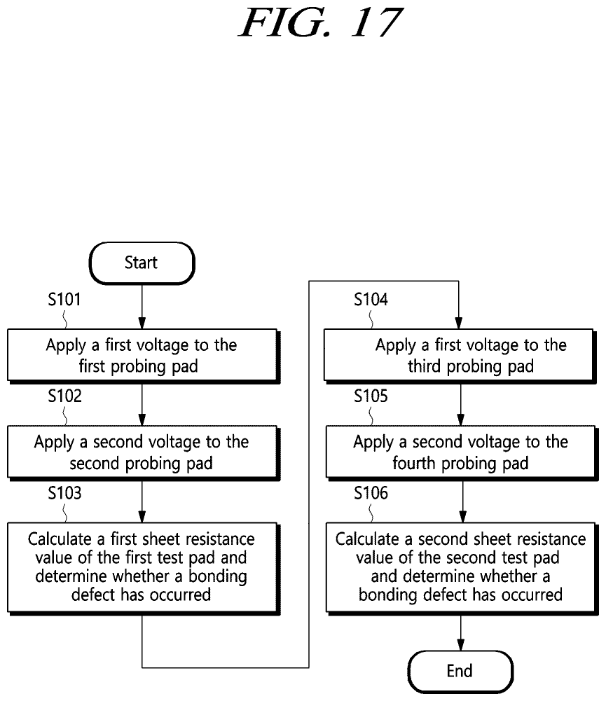

Referring to FIG. 17, a method of detecting a bonding defect in a semiconductor device according to embodiments of the present disclosure may include: applying a first voltage to the first probing pad 293 (S101); applying a second voltage to the second probing pad 294 (S102); determining whether a bonding defect has occurred by calculating a first sheet resistance value of the first test pad TP1 (S103); applying the first voltage to a third probing pad 1193 (S104); applying the second voltage to a fourth probing pad 1194 (S105); and determining whether a bonding defect has occurred by calculating a second sheet resistance value of the second test pad TP2 (S106).

The bonding defect detection method illustrated in FIG. 17 may be applied to a semiconductor device described with reference to FIG. 10 and FIG. 11.

Referring to FIG. 10, FIG. 11, and FIG. 17, the semiconductor device may include the substrate 200; the first test pad TP1; the first probing pad 293; the second probing pad 294; the second test pad TP2 disposed on the same layer as the first test pad TP1 and including the third pad portion PD3 and the fourth pad portion PD4 spaced apart from each other; the third probing pad 1193; the fourth probing pad 1194; the first dummy bonding pad DBP1; and the second dummy bonding pad DBP2.

The third probing pad 1193 may be connected to the third pad portion PD3. The fourth probing pad 1194 may be connected to the fourth pad portion PD4. A first voltage may be applied to the third probing pad 1193, and a second voltage different from the first voltage may be applied to the fourth probing pad 1194.

Referring to Equation 2, a second sheet resistance value of the second test pad TP2 may be calculated based on a current value between the third probing pad 1193 and the fourth probing pad 1194.

In one embodiment, if the second sheet resistance value differs from the first reference value, it may be determined that a bonding defect has occurred. The first reference value may be a sheet resistance value of the second test pad TP2 when the entire top surface of the second test pad TP2 is in the same plane as a top surface of the first bonding insulation layer 230.

In one embodiment, if it is determined that no bonding defect has occurred in the second bonding pad 276, it may then be determined whether a bonding defect has occurred in the first bonding pad 231.

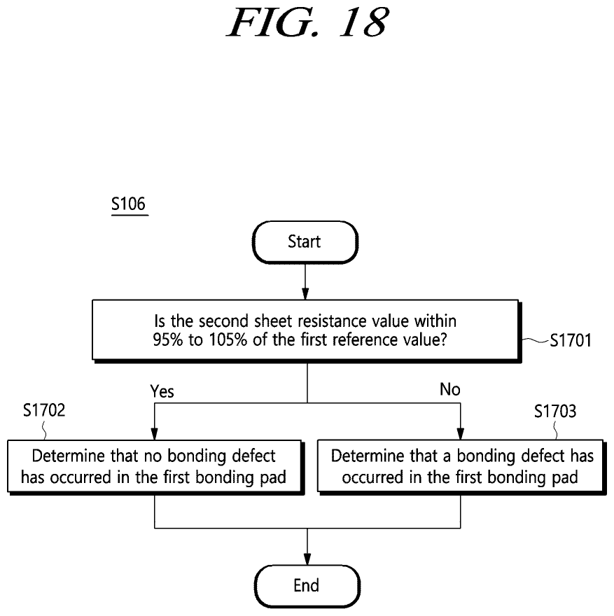

Referring to FIG. 18, the operation (S106) of determining whether a bonding defect has occurred by calculating the second sheet resistance value of the second test pad TP2 may include determining whether the second sheet resistance value is within a range of 95% to 105% of the first reference value (S1701).

If the second sheet resistance value is within the range of 95% to 105% of the first reference value (S1701, Yes), it may be determined that no bonding defect has occurred in the first bonding pad 231 (S1702). If the second sheet resistance value is less than 95% or greater than 105% of the first reference value (S1701, No), it may be determined that a bonding defect has occurred in the first bonding pad 231 (S1703).

According to embodiments of the present disclosure, the semiconductor device may include the first test pad TP1, the first probing pad 293, the second probing pad 294, a second test pad TP2, a third probing pad 1193, and a fourth probing pad 1194. The first test pad TP1 and the second test pad TP2 may be formed in the same process steps as the second bonding pad 276 and the first bonding pad 231, respectively.

When a bonding defect occurs in either the first bonding pad 231 or the second bonding pad 276, the same bonding defect may appear in the first test pad TP1 or the second test pad TP2. Accordingly, by measuring the sheet resistance values of the first test pad TP1 or the second test pad TP2 and comparing them with a predetermined reference value, the disclosed embodiments provide a capability to determine whether a bonding defect has occurred in the first bonding pad 231 or the second bonding pad 276. Therefore, even when the exact thicknesses of the bonding pads are unknown, bonding defects occurring at the bonding interface may be accurately detected.

The foregoing description is merely illustrative of the technical features of the present disclosure. Those skilled in the art to which the present disclosure pertains will appreciate that various modifications and changes can be made without departing from the scope and technical concepts of the present disclosure. Furthermore, the embodiments described herein are provided for illustrative purposes and are not intended to limit the scope of the present disclosure. The protection scope of the present disclosure should be interpreted based on the claims, and all technical concepts falling within the scope of equivalence thereof should be construed as being included within the scope of the present disclosure.

What is claimed is:

1. A semiconductor device comprising:
a first bonding pad disposed on a substrate;
a second bonding pad bonded to the first bonding pad;
a first test pad disposed on a same layer as the second bonding pad, and comprising a first pad portion, a second pad portion spaced apart from the first pad portion, and a first connection portion connecting the first pad portion and the second pad portion;
a first probing pad connected to the first pad portion through first test contacts disposed on the first pad portion; and
a second probing pad connected to the second pad portion through second test contacts disposed on the second pad portion.

2. The semiconductor device according to claim 1, further comprising a first bonding insulation layer surrounding a side surface of the first bonding pad, wherein the first test pad is in contact with a top surface of the first bonding insulation layer.

3. The semiconductor device according to claim 1, further comprising a first bonding insulation layer surrounding a side surface of the first bonding pad, wherein the first test pad is spaced apart from the first bonding insulation layer.

4. The semiconductor device according to claim 1,
wherein an area of a top surface of the first connection portion is greater than an area of a top surface of the first pad portion or an area of a top surface of the second pad portion.

5. The semiconductor device according to claim 1,
wherein a width of the first pad portion in a first direction of a top surface of the substrate is greater than a width of the first connection portion in the first direction.

6. The semiconductor device according to claim 1,
wherein a first voltage is applied to the first probing pad, and
wherein a second voltage different by a predetermined minimum from the first voltage is applied to the second probing pad.

7. The semiconductor device according to claim 1,
wherein the substrate includes a chip region and a scribe lane region located around the chip region, and
wherein the first test pad is disposed in the chip region.

8. The semiconductor device according to claim 1, further comprising:
a second test pad disposed on a same layer as the first bonding pad and spaced apart from the first test pad, the second test pad comprising a third pad portion, a fourth pad portion spaced apart from the third pad portion, and a second connection portion connecting the third pad portion and the fourth pad portion;
a third probing pad connected to the third pad portion through test contacts disposed on the third pad portion; and
a fourth probing pad connected to the fourth pad portion through test contacts disposed on the fourth pad portion.

9. The semiconductor device according to claim 8, further comprising:
a first bonding insulation layer surrounding a side surface of the first bonding pad; and
a second bonding insulation layer bonded to the first bonding insulation layer,
wherein the second test pad is in contact with a bottom surface of the second bonding insulation layer.

10. The semiconductor device according to claim 8, further comprising:
a first bonding insulation layer surrounding a side surface of the first bonding pad; and
a second bonding insulation layer bonded to the first bonding insulation layer,
wherein the second test pad is spaced apart from the second bonding insulation layer.

11. The semiconductor device according to claim 8, further comprising:
a first dummy bonding pad disposed between the test contacts and the third pad portion and connected to the third pad portion; and
a second dummy bonding pad disposed between the test contacts and the fourth pad portion and connected to the fourth pad portion.

12. The semiconductor device according to claim 11,
wherein the first dummy bonding pad and the second dummy bonding pad are in contact with a top surface of the second test pad.

13. The semiconductor device according to claim 11,
wherein the first dummy bonding pad and the second dummy bonding pad are spaced apart from the second test pad.

14. A semiconductor device comprising:
a first semiconductor structure including a first surface and a second surface opposite to the first surface in a direction perpendicular to the first surface; and
a second semiconductor structure bonded to the first semiconductor structure, and including a third surface in contact with the second surface of the first semiconductor structure and a fourth surface located opposite to the third surface in a direction perpendicular to the third surface,
wherein the second semiconductor structure comprises:
a first test pad disposed on the third surface and including a first pad portion, a second pad portion spaced apart from the first pad portion, and a first connection portion connecting the first pad portion and the second pad portion;
a first probing pad disposed on the fourth surface and connected to the first pad portion through first test contacts disposed on the first pad portion; and
a second probing pad disposed on the fourth surface and connected to the second pad portion through second test contacts disposed on the second pad portion.

15. The semiconductor device according to claim 14,
wherein the first semiconductor structure comprises:
a second test pad disposed on the second surface and including a third pad portion, a fourth pad portion spaced apart from the third pad portion, and a second connection portion connecting the third pad portion and the fourth pad portion, the second test pad being spaced apart from the first test pad,
wherein the second semiconductor structure further comprises:
a third probing pad disposed on the fourth surface and connected to the third pad portion through third test contacts disposed on the third pad portion; and
a fourth probing pad disposed on the fourth surface and connected to the fourth pad portion through fourth test contacts disposed on the fourth pad portion.

16. A method of detecting a bonding defect in a semiconductor device comprising a first bonding pad on a substrate, a second bonding pad bonded to the first bonding pad, and a first test pad disposed on the same layer as the second bonding pad and having a first pad portion and a second pad portion spaced apart from each other, the method comprising:
applying a first voltage to a first probing pad connected to the first pad portion;
applying a second voltage to a second probing pad connected to the second pad portion, the second voltage different from the first voltage; and
determining whether a bonding defect has occurred by calculating a first sheet resistance value of the first test pad based on a current value between the first probing pad and the second probing pad.

17. The method according to claim 16,
wherein the determining of whether a bonding defect has occurred by calculating a first sheet resistance value includes determining that a bonding defect has occurred in the second bonding pad when the first sheet resistance value is less than 95% or greater than 105% of a first reference value.

18. The method according to claim 17,
wherein the first reference value is a sheet resistance value of the first test pad when an entire bottom surface of the first test pad is in the same plane as a bottom surface of a bonding insulation layer surrounding a side surface of the first test pad.

19. The method according to claim 17,
wherein the semiconductor device further comprises a second test pad disposed on the same layer as the first bonding pad and including a third pad portion and a fourth pad portion spaced apart from each other, and
the method further comprises:
applying the first voltage to a third probing pad connected to the third pad portion;
applying the second voltage to the fourth pad portion; and
determining whether a bonding defect has occurred by calculating a second sheet resistance value of the second test pad based on a current value between the third probing pad and the fourth probing pad.

20. The method according to claim 19,
wherein the determining of whether a bonding defect has occurred by calculating a second sheet resistance value includes determining that a bonding defect has occurred in the first bonding pad when the second sheet resistance value is less than 95% or greater than 105% of the first reference value.
